(19) United States
(12) Patent Application Publication
(10) Pub. No.: US 2024/0332316 A1
(43) Pub. Date: Oct. 3, 2024

(54) DISPLAY DEVICE

(71) Applicant: Innolux Corporation, Miaoli County (TW)

(72) Inventors: Yi-Shiuan Cherng, Miaoli County (TW); Chia-Hao Tsai, Miaoli County (TW)

(73) Assignee: Innolux Corporation, Miaoli County (TW)

(21) Appl. No.: 18/582,682

(22) Filed: Feb. 21, 2024

(30) Foreign Application Priority Data
Mar. 30, 2023 (CN) 202310325967.6

(51) Int. Cl. H01L 27/12; H01L 25/16

(52) U.S. Cl. CPC H01L 27/124; H01L 25/167

(57) ABSTRACT

A display device including a substrate and a circuit is provided. The substrate has a peripheral region. The circuit is disposed on the peripheral region and includes a plurality of transistors. One of the plurality of transistors includes a semiconductor layer, a first electrode, and a second electrode. The semiconductor layer includes a channel region. The first electrode is disposed at a side of the channel region and includes a first portion. The second electrode is disposed at another side of the channel region and includes a second portion. In a horizontal direction, a width of the first portion of the first electrode is greater than a width of the second portion of the second electrode.

### CROSS-REFERENCE TO RELATED APPLICATION

This application claims the priority benefit of China application serial no. 202310325967.6, filed on Mar. 30, 2023. The entirety of the above-mentioned patent application is hereby incorporated by reference herein and made a part of this specification.

### BACKGROUND

### Technical Field

The disclosure relates to a display device.

### Description of Related Art

As resolution requirements are getting higher, element and circuit layout density in a display device also needs to be increased. Therefore, there is still much room for improvement in the layout of elements and circuits in the display device.

### SUMMARY

The disclosure is directed to a display device that may increase the arrangement density of signal circuits.

According to an embodiment of the disclosure, a display device includes a substrate and a circuit. The substrate has a peripheral region. The circuit is disposed on the peripheral region and includes a plurality of transistors. One of the plurality of transistors includes a semiconductor layer, a first electrode, and a second electrode. The semiconductor layer includes a channel region. The first electrode is disposed at a side of the channel region and includes a first portion. The second electrode is disposed at another side of the channel region and includes a second portion. In a horizontal direction, a width of the first portion of the first electrode is greater than a width of the second portion of the second electrode.

### BRIEF DESCRIPTION OF THE DRAWINGS

FIG. 1 is a schematic top view of a display device of an embodiment of the disclosure.

FIG. 2 is a partial schematic diagram of a circuit applied to the display device of FIG. 1.

FIG. 3 is a partial schematic diagram of a circuit applied to the display device of FIG. 1.

FIG. 4 is a partial schematic diagram of a circuit applied to the display device of FIG. 1.

FIG. 5 is a partial schematic diagram of a circuit applied to the display device of FIG. 1.

FIG. 6 is the schematic cross-sectional view of line I-I in FIG. 5.

FIG. 7 is a partial schematic diagram of a circuit applied to the display device of FIG. 1.

FIG. 8 is a schematic cross-sectional view of line II-II in FIG. 7.

FIG. 9 is a partial schematic diagram of a circuit applied to the display device of FIG. 1.

FIG. 10 is a partial schematic diagram of a circuit applied to the display device of FIG. 1.

FIG. 11 is a partial schematic diagram of a circuit applied to the display device of FIG. 1.

FIG. 12 is a partial schematic diagram of a circuit applied to the display device of FIG. 1.

### DESCRIPTION OF THE EMBODIMENTS

Hereinafter, reference will be made in detail to exemplary embodiments of the disclosure, and examples of the exemplary embodiments are illustrated in the figures. Wherever possible, the same reference numerals are used in the figures and the descriptions to refer to the same or similar portions.

The disclosure may be understood by referring to the following detailed description in conjunction with the accompanying drawings. It should be noted that in order to facilitate understanding to the reader and to simplify the drawings, the multiple drawings in the disclosure depict a part of the display device, and certain elements in the drawings are not drawn to actual scale. In addition, the quantity and dimension of each element in the figures are for illustration, and are not intended to limit the scope of the disclosure.

Certain terms are used throughout the specification and the appended claims of the disclosure to refer to particular elements. Those skilled in the art should understand that electronic equipment manufacturers may refer to the same elements under different names. The present specification is not intended to distinguish between elements having the same function but different names. In the following description and claims, the words “including”, “containing”, “having” and the like are open words, so they should be interpreted as meaning “including but not limited to . . . ” Therefore, when the terms “including”, “containing”, and/or “having” are used in the description of the disclosure, they specify the presence of corresponding features, regions, steps, operations, and/or members, but do not exclude the presence of one or more corresponding features, regions, steps, operations, and/or members.

The terminology mentioned in the specification, such as: “up”, “down”, “front”, “rear”, “left”, “right”, etc., are directions referring to the drawings. Therefore, the directional terms used are for illustration, not for limiting the disclosure. In the drawings, each drawing depicts general features of methods, structures, and/or materials used in specific embodiments. However, these drawings should not be construed to define or limit the scope or nature covered by these embodiments. For example, for clarity, the relative dimension, thickness, and location of each film, area, and/or structure may be reduced or enlarged.

When a corresponding member (e.g., a layer or a region) is referred to as being “disposed or formed on another member”, it may be directly disposed or formed on the other member, or other members may be present in between. Moreover, when a member is referred to as being “directly disposed on or formed on another member”, there are no members in between. In addition, when a member is referred to as “disposed or formed on another member”, the two members have an up-down relationship in the top view, and this member may be above or below the other member, and this up-down relationship depends on the orientation of the device.

It should be understood that when a member or a layer is referred to as being “connected to” another member or layer, it may be directly connected to this other member or layer, or there may be an intervening member or layer between the two. When a member is said to be “directly connected to” another member or layer, there is no intervening member or layer between the two. Moreover, when a member is said to be “coupled to another member (or a variant thereof)”, it may be directly connected to this other member, or indirectly connected (for example, electrically connected) to this other member via one or a plurality of members.

The terms “about”, “substantially”, or “roughly” are generally interpreted as being within 10% of a given value or range, or interpreted as being within 5%, 3%, 2%, 1%, or 0.5% of a given value or range.

The ordinal numbers used in the specification and claims, such as “first”, “second”, etc., are used to modify an element. They do not themselves imply and represent that the element(s) have any previous ordinal quantity, and also do not represent the order of one element and another element, or the order of manufacturing methods. The use of these ordinal numbers is to clearly distinguish an element with a certain name from another element with the same name. The same terms may be not used in the claims and the specification, and accordingly, a first member in the specification may be a second member in the claims.

In the present embodiment, an electronic device may include a display device, a backlight device, an antenna device, a sensing device, or a tiling device, but the disclosure is not limited thereto. The electronic device may be a bendable or flexible electronic device. The display device may be a non-self-luminous type display device or a self-luminous type display device. The antenna device may be a liquid-crystal type antenna device or a non-liquid-crystal type antenna device. The sensing device may be a sensing device for sensing capacitance, light, heat, or ultrasonic waves, but the disclosure is not limited thereto. The tiling device may be, for example, a display tiling device or an antenna tiling device, but the disclosure is not limited thereto. It should be noted that the electronic device may be any combination of the above, but the disclosure is not limited thereto. The following uses a panel-type device as an electronic device to explain the content of the disclosure, but the disclosure is not limited thereto.

In the drawings of the disclosure, X-axis, Y-axis, and Z-axis are marked to indicate the orientation of individual structures. In some embodiments, the X-axis, Y-axis, and Z-axis represent axes intersected in pairs, and the angle at which two axes are intersected may be 90 degrees or other angles.

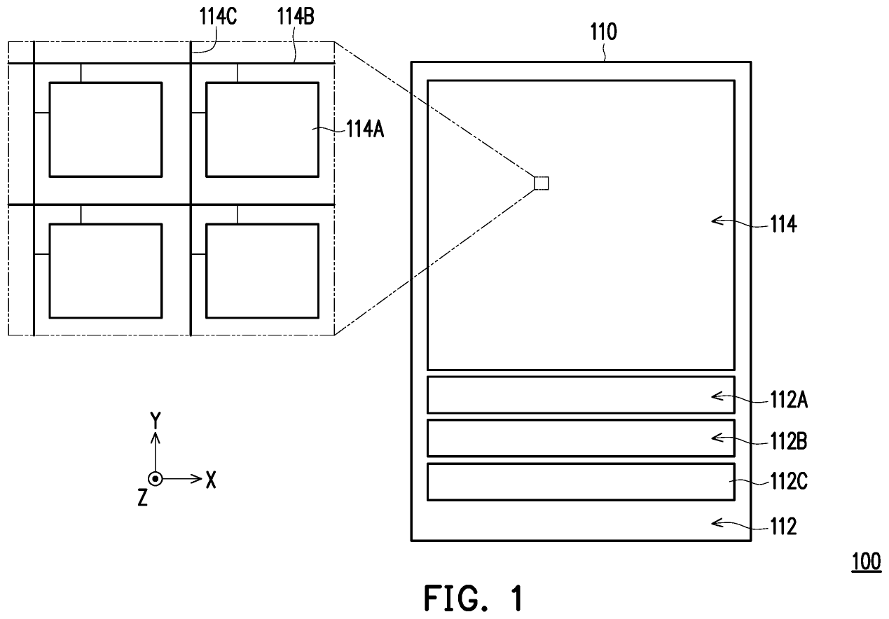

FIG. 1 is a schematic top view of a display device of an embodiment of the disclosure. FIG. 1 substantially shows the regional layout of a display device 100, and a plurality of electronic elements and a plurality of signal lines may be disposed in a single region. The electronic elements may include a sensing element, a passive element, and an active element, such as a sensor, a capacitor, a resistor, an inductor, a diode, a transistor, and the like. The diode may include an LED or a photodiode. The LED may include, for example, an organic light-emitting diode (OLED), a mini LED, a micro LED, or a quantum dot LED, but the disclosure is not limited thereto. The signal line may be connected to the electronic elements as needed, so as to implement the desired signal transmission and electrical connection. In order to clearly illustrate the features of the display device 100, the disclosure may omit descriptions and drawings of some electronic elements and signal lines. However, those skilled in the art should understand that the omitted electronic elements are also provided in the display device 100 to implement the functions of the display device 100.

As shown in FIG. 1, the display device 100 includes a substrate 110. The substrate 110 may have a peripheral region 112 and a display region 114. The display region 114 is adjacent to the peripheral region 112, and the display region 114 may be substantially surrounded by the peripheral region 112. The peripheral region 112 is a region adjacent to the display region 114. The display device 100 may include elements for displaying images in the display region 114, and may also optionally include a sensing element, a light-emitting element, etc. to implement functions such as sensing and emitting light. The display device 100 may be provided with a driving circuit 112A, a test circuit 112B, an integrated circuit (IC) 112C, etc. in the peripheral region 112. The driving circuit 112A and the test circuit 112B disposed in the peripheral region 112 of the display device 100 are not directly used to implement functions such as displaying images, lighting, touch sensing, temperature sensing, and light sensing, but used for testing or driving display elements, light-emitting elements, or sensing elements in the display region 114. The display device 100 mainly implements desired functions by electronic elements disposed in the display region 114, such as displaying images, emitting light, touch sensing, temperature sensing, light sensing, and the like.

In some embodiments, the display device 100 may include a plurality of pixel structures 114A and other elements for displaying images, as well as scan lines 114B and data lines 114C for transmitting signals, wherein the scan lines 114B and the data lines 114C are arranged alternately and define the range of the individual pixel structures 114A. The pixel structures 114A are disposed at the display region 114 of the substrate 110, wherein the peripheral region 112 is adjacent to the display region 114. Individual pixel structures 114A may be connected to one of the data lines 114C and controlled by one of the scan lines 114B. In addition, the individual pixel structures 114A may include at least one transistor (not shown), but the disclosure is not limited thereto. In some embodiments, the pixel structures 114A are arranged in an array. In some embodiments, among the pixel structures 114A, two adjacent columns of the pixel structures 114A may include different types of transistors. In detail, different types of transistors may include transistors that use different semiconductor materials to make channel layers or transistors that use different layers to make channel layers. The semiconductor materials may include silicon semiconductor (such as polysilicon, low-temperature polysilicon, amorphous silicon, microcrystalline silicon, etc.), oxide semiconductor (such as indium gallium zinc oxide, etc.), or organic semiconductor or other suitable materials, but the disclosure is not limited thereto. For example, the pixel structures of the first column adopt low-temperature polysilicon to make the transistors of the channel layer, and the pixel structures of the second column adopt InGaZn oxide to make the transistors of the channel layer. Also, the semiconductor of the pixel structures in the first column is disposed between a first metal layer and a second metal layer, and the semiconductor of the pixel structures in the second column is disposed between a third metal layer and a fourth metal layer, but the disclosure is not limited thereto.

In some embodiments, the driving circuit 112A, the test circuit 112B, and the integrated circuit 112C may be disposed on the substrate 110 and are all located between the display region 114 and one of the edges of the substrate 110, and therefore the display region 114 of the display device 100 may be extended toward the other edges of the substrate 110 as much as possible, which is helpful to implement a narrow border design. In some embodiments, based on the narrow border design, the display device 100 may be applied in a tiling device. In FIG. 1, the driving circuit 112A is disposed between the display region 114 and the test circuit 112B and the test circuit 112B is disposed between the driving circuit 112A and the integrated circuit 112C, but the disclosure is not limited thereto. The driving circuit 112A may be electrically connected to the integrated circuit 112C. In some embodiments, the test circuit 112B is used to test whether the pixel structures 114A or/and the data lines 114C in the display region 114 are abnormal. In addition, the test signal to which the test circuit 112B is connected may be not provided by the integrated circuit 112C but provided by other signal sources. In some embodiments, the integrated circuit 112C may be a packaged chip and may be bonded to substrate 110 using a suitable chip bonding technique.

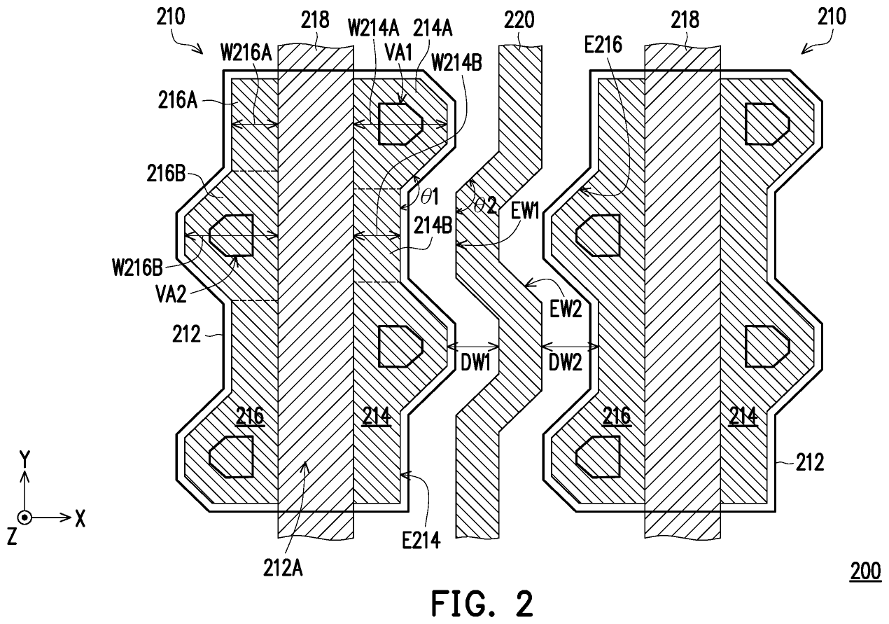

FIG. 2 is a partial schematic diagram of a circuit applied to the display device of FIG. 1. A circuit 200 of FIG. 2 may be disposed on the substrate 110 and disposed on the peripheral region 102. In some embodiments, the circuit 200 may be used to implement at least one of the driving circuit 112A and the test circuit 112B in FIG. 1. The circuit 200 may include a multiplexer circuit or a gate driving circuit. For example, when the circuit 200 is a multiplexer circuit, the circuit 200 may be used to control the signal input of the data lines 114C in the display device 100 of FIG. 1. When the circuit 200 is a gate driving circuit, the circuit 200 may be used to control the signal of the scan lines 114B in the display device 100 of FIG. 1.

The circuit 200 includes a plurality of transistors 210, and FIG. 2 uses two adjacent transistors 210 for illustration. The so-called two adjacent transistors 210 means that there are no other transistors 210 between the two transistors 210, but does not exclude the presence of other elements between the two transistors 210. Referring to FIG. 2, the circuit 200 further includes a signal line 220, and the signal line 220 is disposed between two adjacent transistors 210. Moreover, although FIG. 2 shows that one signal line 220 is disposed between two adjacent transistors 210, in some embodiments, a plurality of signal lines 220 may be disposed between two adjacent circuits 200 of the transistors 210.

In the present embodiment, one of the transistors 210 includes a semiconductor layer 212, a first electrode 214, a second electrode 216, and a gate 218. The semiconductor layer 212 includes a channel region 212A. The first electrode 214 is disposed at a side of the channel region 212A, and the second electrode 216 is disposed at another side of the channel region 212A. In some embodiments, in a top view, the channel region 212A is a portion in the semiconductor layer 212 between the first electrode 214 and the second electrode 216, and the channel region 212A is at least partially overlapped with the gate 218. The material of the semiconductor layer 212 includes silicon semiconductor (such as polysilicon, low-temperature polysilicon, amorphous silicon, microcrystalline silicon, etc.), oxide semiconductor (such as indium gallium zinc oxide, etc.), or organic semiconductor or other suitable materials, but the disclosure is not limited thereto, and the material of the first electrode 214, the second electrode 216, and the gate 218 includes metal (for example: copper, molybdenum, aluminum), transparent metal oxide (e.g.: ITO, IZO) or other conductive materials. The first electrode 214 may be a source or a drain. The second electrode 216 may be a source or a drain.

As shown in FIG. 2, the first electrode 214 and the second electrode 216 are substantially extended along the longitudinal direction, and have a width variation in the direction of the Y-axis, wherein the so-called width here is substantially a dimension measured in the horizontal direction. The longitudinal direction may be parallel to the Y-axis, for example, and the horizontal direction may be parallel to the X-axis, for example. In addition, the first electrode 214 and the second electrode 216 located at two opposite sides of the channel region 212A present a nonlinear symmetrical structure design. For example, when measured along the same line parallel to the X-axis, the dimensions of the first electrode 214 and the second electrode 216 are different. In some embodiments, the first electrode 214 may include a first portion 214A, the second electrode 216 may include a second portion 216A, and in the horizontal direction (X-axis), a width W214A of the first portion 214A of the first electrode 214 is greater than a width W216A of the second portion 216A of the second electrode 216. The first portion 214A of the first electrode 214 and the second portion 216A of the second electrode 216 are arranged at the same line on the horizontal direction (X-axis), and the first portion 214A of the first electrode 214 and the second portion 216A of the second electrode 216 are asymmetrical to each other.

The second electrode 216 also includes a third portion 216B. The third portion 216B is adjacent to the second portion 216A. The first electrode 214 may further include a fourth portion 214B adjacent to the first portion 214A. In the present embodiment, the third portion 216B is adjacent to the second portion 216A in the longitudinal direction (Y-axis), and a width W216B of the third portion 216B is greater than the width W216A of the second portion 216A. For example, the width W216B of the third portion 216B may be substantially equal to the width W214A of the first portion 214A of the first electrode 214 and the third portion 216B is offset from the first portion 214A of the first electrode 214 in the horizontal direction (X-axis). Similarly, the fourth portion 214B is adjacent to the first portion 214A in the longitudinal direction (Y-axis), and a width W214B of the fourth portion 214B is less than the width W214A of the first portion 214A. For example, the width W214B of the fourth portion 214B may be substantially equal to the width W216A of the second portion 216A of the second electrode 216 and the fourth portion 214B is offset from the second portion 216A of the second electrode 216 in the horizontal direction (X-axis).

The first portion 214A of the first electrode 214 may be electrically connected to the semiconductor layer 212 via a hole VA1, and the third portion 216B of the second electrode 216 may be electrically connected to the semiconductor layer 212 via another hole VA2. The second portion 216A of the second electrode 216 and the fourth portion 214B of the first electrode 214 have no corresponding holes. Therefore, the second portion 216A of the second electrode 216 and the fourth portion 214B of the first electrode 214 may be not in contact with the semiconductor layer 212. The so-called “holes” term herein may be understood as a structure in which the insulating layer between the semiconductor layer 212 and the electrode is hollowed out, and the conductive material of the electrodes or other conductive materials may be filled in the so-called “holes” and be in contact with the semiconductor layer 212, so as to implement the electrical connection between the electrodes and the semiconductor layer.

In the present embodiment, the first portion 214A of the first electrode 214 and the third portion 216B of the second electrode 216 are wider portions in the individual electrodes, and therefore the hole VA1 disposed corresponding to the first portion 214A and the hole VA2 disposed corresponding to the third portion 216B may have a sufficient size to ensure that the first electrode 214 and the second electrode 216 may be respectively electrically connected to the semiconductor layer 212. The second portion 216A of the second electrode 216 and the fourth portion 214B of the first electrode 214 are relatively narrower portions, thus facilitating the reduction of the area of the transistors 210.

As shown in FIG. 2, the signal line 220 is disposed between two adjacent transistors 210, and the signal line 220 is a curve-shaped circuit extended substantially along the longitudinal direction (Y-axis). In the present embodiment, the signal line 220 is adjacent to the first electrode 214 of the transistor 210 at the left in FIG. 2, and the signal line 220 is bent along the contour of the first electrode 214. Specifically, the first electrode 214 includes a wider first portion 214A and a narrower fourth portion 214B, and the first electrode 214 is substantially formed by alternately connecting the first portion 214A and the fourth portion 214B. Accordingly, the first electrode 214 may have a bent outer edge E214 and the outer edge E214 has a first bending angle θ1. In some embodiments, the first bending angle θ1 is, for example, 100° to 160° (100°≤angle θ1≤160°). In some embodiments, the signal line 220 has a second bending angle θ2, and the difference between the second bending angle θ2 and the first bending angle θ1 is within 10 degrees. In some embodiments, an edge EW1 of the signal line 220 is adjacent to the first electrode 214 of the transistor 210 at the left, and a separation distance DW1 between the outer edge E214 of the first electrode 214 and the edge EW1 of the signal line 220 in the horizontal direction (X-axis), for example, is substantially maintained constant or may be fine-tuned according to wiring requirements. Moreover, an edge EW2 of the signal line 220 is adjacent to the second electrode 216 of the transistor 210 at the right, and a separation distance DW2 between an outer edge E216 of the second electrode 216 and the edge EW2 of the signal line 220 in the horizontal direction (X-axis), for example, is substantially maintained constant or may be fine-tuned according to wiring requirements. In some embodiments, the first electrode 214 may have a curved outer edge, and the outer edge has an arc angle; the second electrode 216 may have a curved outer edge, and the outer edge has an arc angle. In some embodiments, the shape of the signal line 220 may be wavy, but the disclosure is not limited thereto.

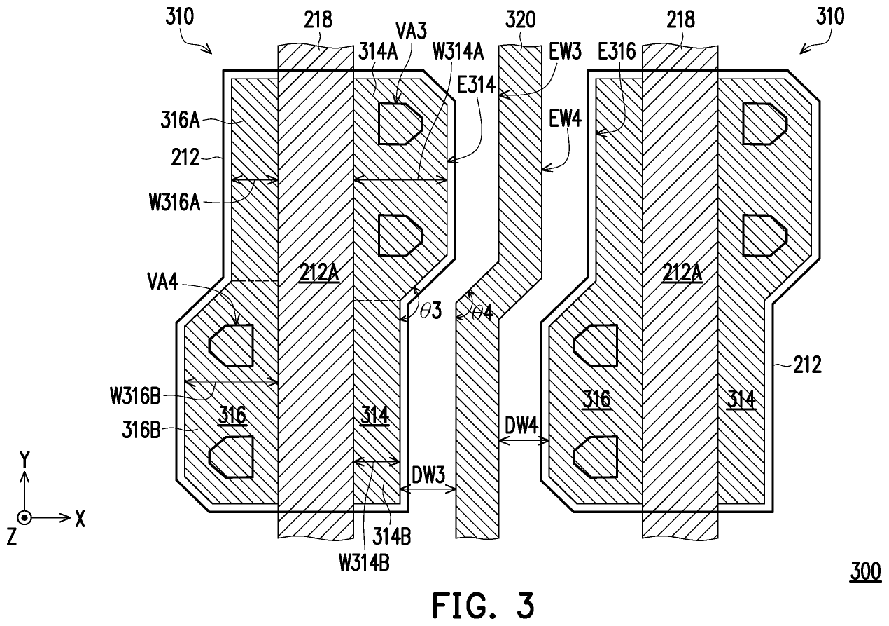

FIG. 3 is a partial schematic diagram of a circuit applied to the display device of FIG. 1. A circuit 300 of FIG. 3 may be a variant implementation of the circuit 200, so the same reference numerals in the two embodiments are used to denote the same elements, and the descriptions of individual elements are comparable to each other. The circuit 300 includes a plurality of transistors 310 and signal lines 320, and the signal lines 320 are located between two adjacent transistors 310. One of the transistors 310 includes the semiconductor layer 212, a first electrode 314, a second electrode 316, and the gate 218. The difference between the transistors 310 and the transistors 210 of FIG. 2 is in the contour design of the first electrode 314 and the second electrode 316.

Specifically, the first electrode 314 and the second electrode 316 respectively include a plurality of portions. A first portion 314A of the first electrode 314 and a second portion 316A of the second electrode 316 are opposite to each other in the horizontal direction (X-axis), that is, located at two opposite sides of the channel region 212A of the semiconductor layer 212. A width W314A of the first portion 314A of the first electrode 314 is greater than a width W316A of the second portion 316A of the second electrode 316. At the same time, the first portion 314A of the first electrode 314 may be electrically connected to the semiconductor layer 212 via a plurality of holes VA3, and the second portion 316A of the second electrode 316 is not directly connected to the semiconductor layer 212. The second electrode 316 also includes a third portion 316B, the third portion 316B is adjacent to the second portion 316A in the longitudinal direction (Y-axis), for example, and the third portion 316B of the second electrode 316 may be electrically connected to the semiconductor layer 212 via a plurality of holes VA4. In other words, the second portion 316A of the second electrode 316 is not directly connected to the semiconductor layer 212, but may be electrically connected to the semiconductor layer 212 via the third portion 316B and the holes VA4. Moreover, the first electrode 314 further includes a fourth portion 314B, the fourth portion 314B is adjacent to the first portion 314A in the longitudinal direction (Y-axis), wherein the fourth portion 314B of the first electrode 314 is not directly connected to the semiconductor layer 212 but electrically connected to the semiconductor layer 212 via the first portion 314A and the holes VA3.

In the present embodiment, the width W314A of the first portion 314A of the first electrode 314 is greater than the width W314B of the fourth portion 314B, and the width W316B of the third portion 316B of the second electrode 316 is greater than the width W316A of the second portion 316A. The plurality of holes VA3 are disposed corresponding to the relatively wide first portion 314A of the first electrode 314 to implement that the first electrode 314 is electrically connected to the semiconductor layer 212, and the plurality of holes VA4 correspond to the relatively wide third portion 316B in the second electrode 316 to implement the electrical connection of the second electrode 316 to the semiconductor layer 212, thus ensuring that the first electrode 314 and the second electrode 316 are electrically connected to the semiconductor layer 212. The fourth portion 314B of the first electrode 314 and the second portion 316A of the second electrode 316 not corresponding to the holes are relatively narrower portions in the electrodes, thus facilitating the reduction of the area of the transistors 310, so that the signal lines 320 may be arranged more densely.

In some embodiments, an outer edge E314 of the first electrode 314 located at the left transistor 310 is adjacent to the signal lines 320, and there is a first bending angle θ3 between the first portion 314A and the fourth portion 314B. An edge EW3 of the signal lines 320 is substantially bent along with the outer edge E314 and has a second bending angle θ4. In some embodiments, the difference between the first bending angle θ3 and the second bending angle θ4 is within 10 degrees. In some embodiments, the first bending angle θ3 is substantially 100 degrees to 160 degrees. In some embodiments, in the horizontal direction (X-axis), the separation distance DW2 between the outer edge E314 and the edge EW3 may be substantially maintained constant. Similarly, an outer edge E316 of the second electrode 316 of the transistor 310 located at the right is adjacent to the signal lines 320, and an edge EW4 of the signal lines 320 is bent substantially along the outer edge E316. In some embodiments, in the horizontal direction (X-axis), a separation distance DW4 between the outer edge E316 and the edge EW4 may be substantially maintained constant.

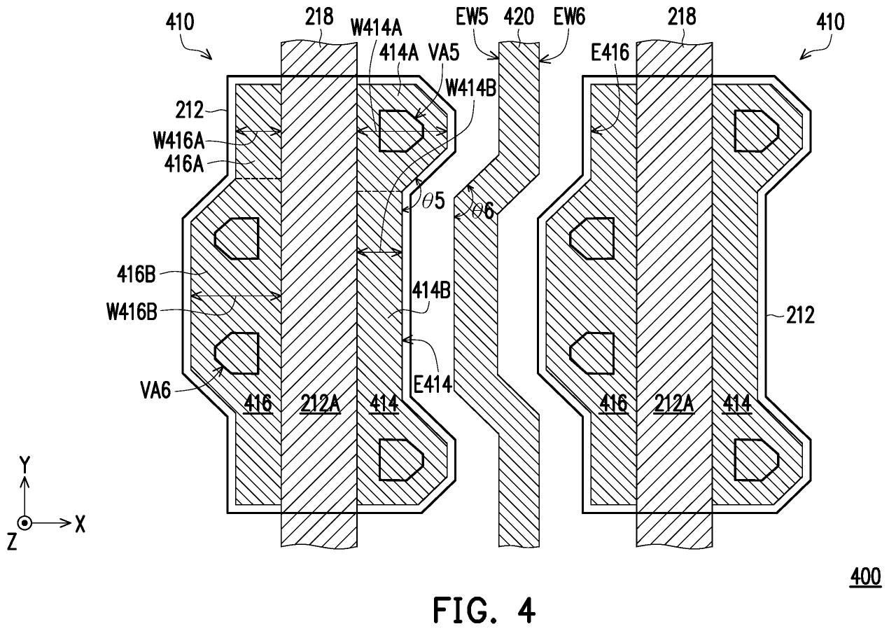

FIG. 4 is a partial schematic diagram of a circuit applied to the display device of FIG. 1. A circuit 400 of FIG. 4 may be a variant implementation of the circuit 200, so the same reference numerals in the two embodiments are used to denote the same elements, and the descriptions of individual elements are comparable to each other. The circuit 400 of FIG. 4 includes a plurality of transistors 410 and signal lines 420, wherein the signal lines 420 are located between two adjacent transistors 410. In the present embodiment and the embodiment in FIG. 2, the same reference numerals represent the same elements, and therefore the relevant descriptions of the corresponding elements are comparable to each other. Specifically, the present embodiment is different from the embodiment of FIG. 2 mainly in the contour design of the electrodes. One of the transistors 410 includes the semiconductor layer 212, a first electrode 414, a second electrode 416, and the gate 218. The electrical relationship of the semiconductor layer 212, the first electrode 414, the second electrode 416, and the gate 218 is as provided for the semiconductor layer 212, the first electrode 214, the second electrode 216, and the gate 218 of FIG. 2. However, the contour shapes of the first electrode 414 and the second electrode 416 are different from those of the first electrode 214 and the second electrode 216 of FIG. 2.

In the present embodiment, the first electrode 414 includes a first portion 414A that may be electrically connected to the semiconductor layer 212 via a hole VA5. The second electrode 416 includes a second portion 416A corresponding to the first portion 414A. For example, the first portion 414A and the second portion 416A are arranged at two opposite sides of the channel region 212A along the horizontal direction (X-axis). The second portion 416A of the second electrode 416 may not correspond to any hole, and a width W414A of the first portion 414A of the first electrode 414 is greater than a width W416A of the second portion 416A of the second electrode 416.

In addition, the second electrode 416 further includes a third portion 416B, and the third portion 416B is adjacent to the second portion 416A. At the same time, the first electrode 414 further includes a fourth portion 414B, and the fourth portion 414B is adjacent to the first portion 414A. The third portion 416B of the second electrode 416 is wider than the second portion 416A, and may be electrically connected to the semiconductor layer 212 via a plurality of holes VA6, and the fourth portion 414B of the first electrode 414 is narrower than the first portion 414A and does not correspond to a hole. In the present embodiment, the first portion 414A of the first electrode 414 and the third portion 416B of the second electrode 416 have different extending lengths in the longitudinal direction (Y-axis). In this way, the first portion 414A of the first electrode 414 and the third portion 416B of the second electrode 416 may correspond to different numbers of holes. For example, the first portion 414A of the first electrode 414 corresponds to one hole VA5, and the third portion 416B of the second electrode 416 corresponds to two holes. Moreover, the fourth portion 414B of the first electrode 414 and the third portion 416B of the second electrode 416 may have similar or same extending lengths in a longitudinal direction (Y-axis). In this way, the third portion 416B of the second electrode 416 and the fourth portion 414B of the first electrode 414 may compensate each other in width. Similarly, the second portion 416A of the second electrode 416 and the first portion 414A of the first electrode 414 may also compensate each other in width. Moreover, the first electrode 414 may include two first portions 414A and the fourth portion 414B sandwiched between the two first portions 414A, and the second electrode 416 may include two second portions 416A and the third portion 416B sandwiched between the two second portions 416A, so that the electrode profiles of the transistor 410 are complementary, but the disclosure is not limited thereto.

Similar to the previous embodiments, the signal lines 420 are located between two transistors 410 and have an edge EW5 and an edge EW6 adjacent to the right transistor 410. The edge EW5 of the signal lines 420 is adjacent to the first electrode 414 of the left transistor 410, and the edge EW5 may be bent along the outer edge E414 of the first electrode 414 of the left transistor 410. The edge EW6 of the signal line 420 is adjacent to the second electrode 416 of the right transistor 410, and the edge EW6 may be bent along the outer edge E416 of the second electrode 416 of the right transistor 410. The outer edge E414 has a first bending angle θ5 between the first portion 414A and the fourth portion 414B, and the edge EW5 has a corresponding second bending angle θ6, and the difference between the first bending angle θ5 and the second bending angle θ6 is within 10 degrees. Moreover, in the horizontal direction (X-axis), the separation distance between the outer edge E414 and the edge EW5 and the separation distance between the outer edge E416 and the edge EW6 may be maintained constant.

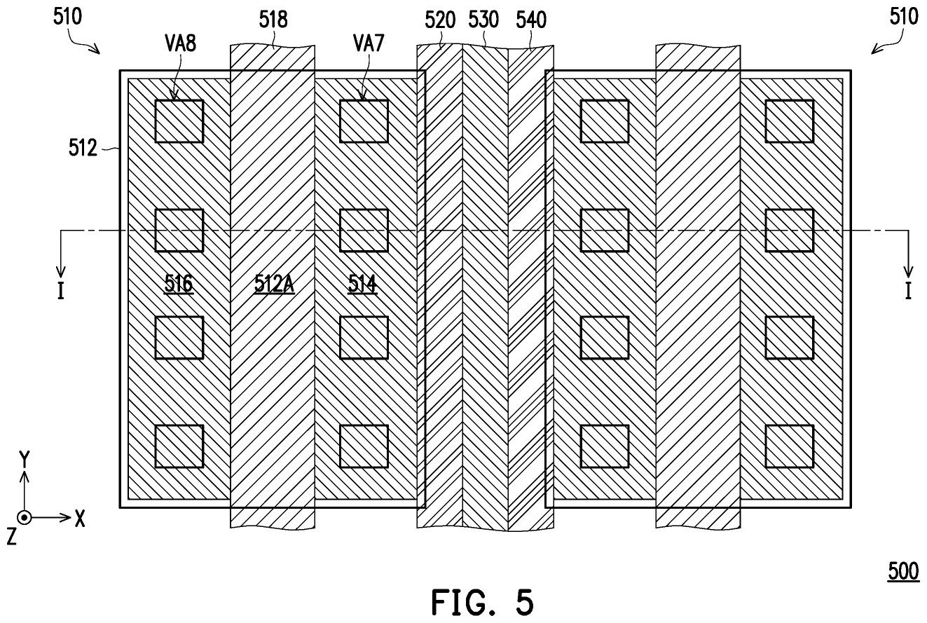

FIG. 5 is a partial schematic diagram of a circuit applied to the display device of FIG. 1. A circuit 500 of FIG. 5 may be disposed on the substrate 110 of FIG. 1, and specifically disposed on the peripheral region 112. The circuit 500 of FIG. 5 includes a plurality of transistors 510 and a plurality of signal lines (such as a first signal line 520, a second signal line 530, and a third signal line 540), wherein the first signal line 520, the second signal line 530, and the third signal line 540 are located between two adjacent transistors 510. The present embodiment takes three signal lines as an example for illustration, but in other embodiments, any other number, such as 2 or more than 3 signal lines, may be disposed between two adjacent transistors 510.

One of the transistors 510 may include a semiconductor layer 512, a first electrode 514, a second electrode 516, and a gate 518. In addition, for the convenience of description, the transistor 510 in FIG. 5 is presented in a schematic manner, and the transistor 510 may specifically have any structure recited in FIG. 2 to FIG. 4. For example, in FIG. 5, although the first electrode 514 and the second electrode 516 have a rectangular shape as an example in FIG. 5, they may be modified to other implementations in the above embodiments. In other words, the first electrode 514 and the second electrode 516 may have the structure of the first electrode 214 and the second electrode 216, the structure of the first electrode 314 and the second electrode 316, or the structure of the first electrode 414 and the second electrode 416. Similarly, the semiconductor layer 512 and the gate 518 may also be as provided in the semiconductor layer 212 and the gate 218 of the above embodiments.

In the present embodiment, the semiconductor layer 512 has a channel region 512A overlapped with the gate 518, and the first electrode 514 and the second electrode 516 are located at different sides of the channel region 512A. The first electrode 514 may be electrically connected to the semiconductor layer 512 via a hole VA7, and the second electrode 516 may be electrically connected to the semiconductor layer 512 via a hole VA8. Moreover, the first signal line 520, the second signal line 530, and the third signal line 540 are disposed between two adjacent transistors 510, and among the first signal line 520, the second signal line 530, and the third signal line 540, at least the first signal line 520 and the second signal line 530 are not the same layer. In the present embodiment, the first signal line 520, the second signal line 530, and the third signal line 540 may all be different layers, but the disclosure is not limited thereto. When applied to the display device 100 of FIG. 1, the first signal line 520 and the second signal line 530 may respectively control the pixel structures 114A of different rows.

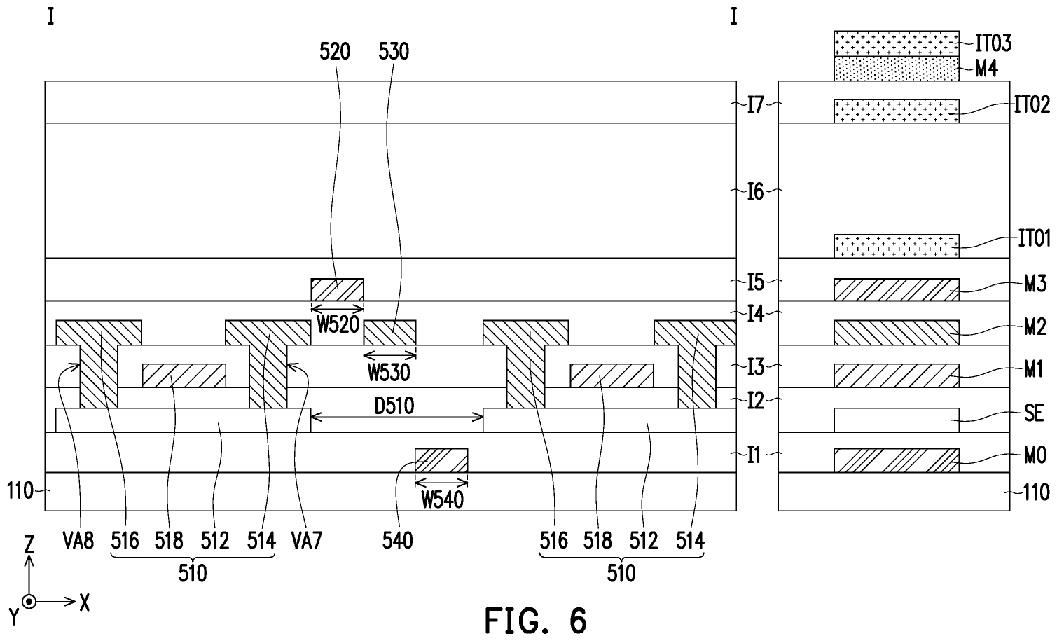

FIG. 6 is the schematic cross-sectional view of line I-I in FIG. 5. Referring to FIG. 5 and FIG. 6 at the same time, the circuit 500 may be manufactured using, for example, the layers used to manufacture the pixel structures 114A in the display device 100. For convenience of illustration, the schematic diagram at the right side of FIG. 6 shows the layers for manufacturing the pixel structures 114A. In some embodiments, the layers of the conductive materials in the layers include conductive layers M0 to M4 and conductive layers ITO1 to ITO3, and the layers of the conductive materials are stacked from the substrate 110 along the Z-axis in the following order: the conductive layer M0, the conductive layer M1, the conductive layer M2, the conductive layer M3, the conductive layer ITO1, the conductive layer ITO2, the conductive layer M4, and the conductive layer ITO3. However, such layer quantity and stacking method are for illustration, and other embodiments may be different. The conductive layers M0 to M4 may be understood as conductive layers formed by metal material, and the conductive layers ITO1 to ITO3 may be understood as transparent conductive layers having light transmission, but the disclosure is not limited thereto. In order to implement the desired electrical function, a semiconductor material layer SE is further included between the conductive layer M0 and the conductive layer M1. In addition, a plurality of insulating layers I1 to 17 are disposed on the substrate 110 to separate adjacent conductive layers M0 to M4 and ITO1 to ITO3.

In FIG. 6, the semiconductor layer 512 of the transistor 510 is formed by the semiconductor material layer SE, and is disposed on the insulating layer I1. The insulating layer 12 covers the semiconductor layer 512, and the gate 518 is disposed on the insulating layer 12. The gate 518 formed by the conductive layer M1 may be overlapped with the semiconductor layer 512, and the insulating layer 12 is located between the gate 518 and the semiconductor layer 512 as a gate insulating layer. The insulating layer 13 covers the gate 518, and the first electrode 514 and the second electrode 516 formed by the conductive layer M2 are disposed on the insulating layer 13. The insulating layer 13 and the insulating layer 12 are stacked continuously between the conductive layer M2 and the semiconductor material layer SE. Here, the hole VA7 and the hole VA8 penetrate through the insulating layer 12 and the insulating layer 13, and a portion of the first electrode 514 and the second electrode 516 is filled in the hole VA7 and the hole VA8 to be in contact with the semiconductor layer 512. Therefore, the hole VA7 and the hole VA8 may be overlapped with the first electrode 514 and the second electrode 516 respectively. The insulating layers 14 to 17 are sequentially stacked on the transistor 510.

Moreover, in the present embodiment, the first signal line 520 and the second signal line 530 adjacent to each other are different layers, wherein the first signal line 520 is formed by, for example, the conductive layer M3, and the second signal line 530 is formed by, for example, the conductive layer M2. Similarly, the second signal line 530 and the third signal line 540 adjacent to each other are different layers, wherein the second signal line 530 is formed by the conductive layer M2, for example, and the third signal line 540 is formed by the conductive layer M0, for example. In this way, the distance between two adjacent signal lines in the horizontal direction (X-axis) may be reduced as much as possible to achieve a high configuration density. In some embodiments, the first signal line 520 and the second signal line 530 may be adjacent to each other in the horizontal direction (X-axis) so that the contours of the first signal line 520 and the second signal line 530 are aligned with each other in a top view (e.g., FIG. 5). In some embodiments, the contours of the first signal line 520 and the second signal line 530 may be partially overlapped with each other, or even completely overlapped with each other in a top view (e.g., FIG. 5). Similarly, the second signal line 530 and the third signal line 540 are different layers, and may be disposed adjacent to each other in the horizontal direction (X-axis). In this way, the signal lines between two adjacent transistors 510 may be closely arranged to facilitate disposing a desired number of signal lines in a limited area.

Since the first signal line 520, the second signal line 530, and the third signal line 540 may be closely arranged, a separation distance D510 between two adjacent transistors 510 (for example, the separation distance between the semiconductor layers 512 of two transistors 510) may be substantially the sum of a width W520 of the first signal line 520, a width W530 of the second signal line 530, and a width W540 of the third signal line 540, and may even be less than the sum of the width W520, the width W530, and the width W540. Therefore, the circuit 500 has good layout area utilization.

In some embodiments, when the circuit 500 is used to implement a multiplexer circuit, the third signal line 540 formed by the conductive layer M0 and the first signal line 520 formed by the conductive layer M3 may be used to transmit control signals, source signals of other transistors, or drain signals of other transistors, etc. In some embodiments, when the circuit 500 is used to implement a gate driving circuit, the third signal line 540 formed by the conductive layer M0 and the first signal line 520 formed by the conductive layer M3 may be used to transmit the signal of the scan lines 114B in the display region 114, the timing signal, or the signal of an internal node of the gate driving circuit.

Although FIG. 6 is used to illustrate the cross-sectional structure of the transistor 510, it may also be applied to the cross-sectional implementation of the transistor in any of FIG. 2 to FIG. 4. In other words, any of the transistors 210, 310, and 410 may have the cross-sectional structure of the transistor 510 shown in FIG. 6. This means that any of the transistors 210, 310, and 410 may be manufactured using the layers used to manufacture the pixel structures 114A.

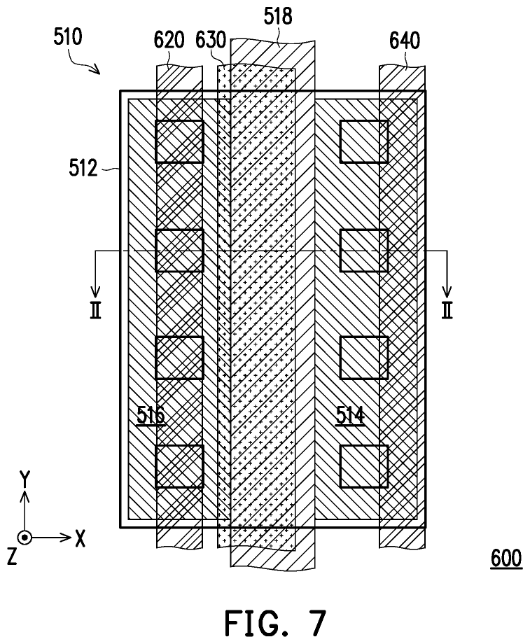

FIG. 7 is a partial schematic diagram of a circuit applied to the display device of FIG. 1. A circuit 600 of FIG. 7 may be disposed on the substrate 110 of FIG. 1, and specifically disposed on the peripheral region 102. The circuit 600 of FIG. 7 includes a plurality of transistors 510 and a plurality of signal lines (such as a first signal line 620, a second signal line 630, and a third signal line 640), wherein for convenience of illustration, FIG. 7 shows one transistor 510 and the transistor 510 of FIG. 7 may be as provided for the transistor 510 of FIG. 5. In the present embodiment, the first signal line 620, the second signal line 630, and the third signal line 640 are different layers, and the first signal line 620, the second signal line 630, and the third signal line 640 may be partially overlapped with the transistor 510.

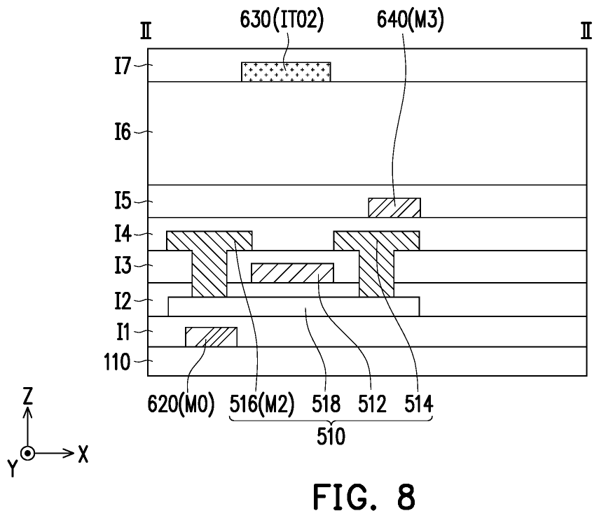

FIG. 8 is a schematic cross-sectional view of line II-II in FIG. 7. Referring to FIG. 7 and FIG. 8 at the same time, the circuit 600 disposed in the display device 100 may be manufactured using the layers of the pixel structures 114A in the display region 114. Therefore, for the stacking relationship of the layers of FIG. 8, reference may be made to the related description of FIG. 6. In addition, the transistor 510 of FIG. 8 is substantially the same as the transistor 510 of FIG. 6, so the cross-sectional structure of the transistor 510 may be as provided in the description of FIG. 6, and is not repeated herein. In the present embodiment, the first signal line 620, the second signal line 630, and the third signal line 640 may be formed by the conductive layer M0, the conductive layer ITO2, and the conductive layer M3 respectively. Therefore, the first signal line 620 is disposed between the substrate 110 and the insulating layer I1, the second signal line 630 is disposed between the insulating layer 16 and the insulating layer 17, and the third signal line 640 is disposed between the insulating layer 14 and the insulating layer 15.

The first signal line 620 may be overlapped with the second electrode 516 of the transistors 510. The second electrode 516 is formed by the conductive layer M2, and the first signal line 620 is formed by the conductive layer M0. Therefore, the insulating layers I1 to I3 are disposed between the first signal line 620 and the second electrode 516 to reduce signal interference and parasitic capacitance between the first signal line 620 and the second electrode 516. The second signal line 630 may be overlapped with the gate 518 of the transistors 510. The gate 518 is formed by the conductive layer M1, and the second signal line 630 is formed by the conductive layer ITO2. Therefore, the insulating layers I3 to I6 are disposed between the second signal line 630 and the gate 518 to reduce signal interference and parasitic capacitance between the second signal line 630 and the gate 518. The third signal line 640 may be overlapped with the first electrode 514 of the transistors 510. The first electrode 514 is formed by the conductive layer M2, and the third signal line 640 is formed by the conductive layer M3. Therefore, the insulating layer I4 is disposed between the third signal line 640 and the first electrode 514 to reduce signal interference and parasitic capacitance between the third signal line 640 and the first electrode 514. Since the first signal line 620, the second signal line 630, and the third signal line 640 are different layers, and the first signal line 620, the second signal line 630, and the third signal line 640 are different layers from the electrodes of the transistor 510, the first signal line 620, the second signal line 630, and the third signal line 640 may be overlapped with the transistors 510 to reduce the arrangement area of the circuit 500. In some embodiments, since the gate 518 needs a greater voltage input, when the gate 518 is formed by the conductive layer M1, the signal line formed by the conductive layer M0 or the conductive layer M2 is not overlapped with the gate 518, thus reducing the voltage of the signal line affecting the voltage of the gate 518 and causing abnormal electrical properties of the transistors, but the disclosure is not limited thereto.

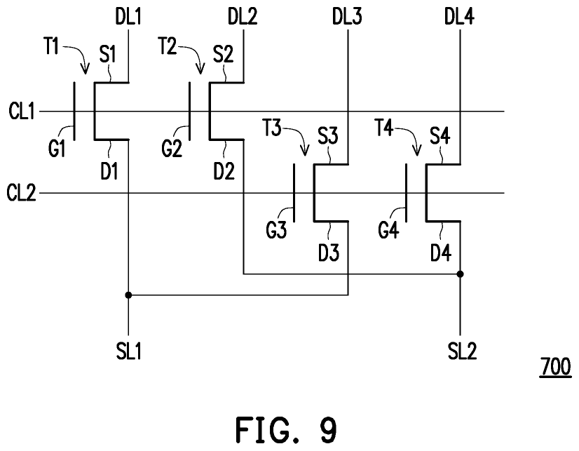

FIG. 9 is a partial schematic diagram of a circuit applied to the display device of FIG. 1. A circuit 700 of FIG. 9 includes a plurality of transistors T1 to T4, a plurality of control lines CL1 and CL2, a plurality of data lines DL1 to DL4, and a plurality of signal lines SL1 and SL2. The transistor T1 may include a gate G1, a first electrode S1, and a second electrode D1, the transistor T2 may include a gate G2, a first electrode S2, and a second electrode D2, the transistor T3 may include a gate G3, a first electrode S3, and a second electrode D3, and the transistor T4 may include a gate G4, a first electrode S4, and a second electrode D4. The gate G1 and the gate G2 are connected to the control line CL1, and the gate G3 and the gate G4 are connected to the control line CL2. Meanwhile, the first electrode S1 is connected to the data line DL1, the second electrode D2 is connected to the data line DL2, the third electrode S3 is connected to the data line DL3, and the fourth electrode S4 is connected to the data line DL4. Therefore, both the transistor T1 and the transistor T2 are controlled by the control line CL1, and both the transistor T3 and the transistor T4 are controlled by the control line CL2. In addition, the transistor T1, the transistor T2, the transistor T3, and the transistor T4 are respectively connected to the data line DL1, the data line DL2, the data line DL3, and the data line DL4. In some embodiments, the specific structures of the transistor T1, the transistor T2, the transistor T3, and the transistor T4 may be implemented by any of the transistors 210, 310, 410, and 510.

In the present embodiment, the second electrode D1 of the transistor T1 is connected to the second electrode D3 of the transistor T3, and the second electrode D2 of the transistor T2 is connected to the second electrode D4 of the transistor T4. The second electrode D1 of the transistor T1 and the second electrode D3 of the transistor T3 are commonly connected to the signal line SL1, and the second electrode D2 of the transistor T2 and the second electrode D4 of the transistor T4 are commonly connected to the signal line SL2. In this way, the circuit 700 may be a multiplexer circuit, but the disclosure is not limited thereto.

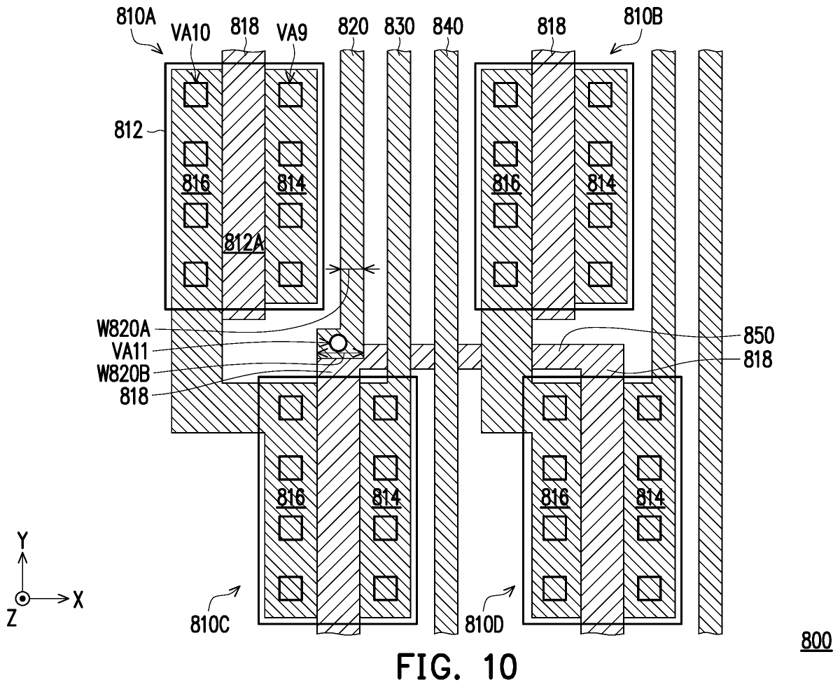

FIG. 10 is a partial schematic diagram of a circuit applied to the display device of FIG. 1. A circuit 800 of FIG. 10 may be disposed on the substrate 110 of FIG. 1, and specifically disposed on the peripheral region 112 of FIG. 1. The circuit 800 includes a plurality of transistors 810A to 810D and a plurality of signal lines 820, 830, and 840. The transistors 810A to 810D are arranged in an array, wherein the transistor 810A and the transistor 810B are arranged in a column in the horizontal direction (X-axis), and the transistor 810C and the transistor 810D are arranged in another column in the horizontal direction (X-axis). The transistor 810A and the transistor 810C are arranged in the longitudinal direction (Y-axis) and staggered from each other, and the transistor 810B and the transistor 810D are arranged in the longitudinal direction (Y-axis) and staggered from each other. In the present embodiment, each of the transistors 810A to 810D includes a channel layer 812, a first electrode 814, a second electrode 816, and a gate 818. The channel layer 812 has a channel region 812A. The channel region 812A is overlapped with the gate 818 and the first electrode 814 and the second electrode 816 are located at different sides of the channel region 812A. The first electrode 814 and the second electrode 816 may be electrically connected to the semiconductor layer 812 via holes VA9 and VA10 respectively. The specific structure of the transistors 810A to 810D may be implemented by any of the transistors 210, 310, 410, and 510. For example, the extending lines of the holes VA9 and VA10 in the horizontal direction (X-axis) may be not overlapped, and the portion of the first electrode 814 between the holes VA9 has a narrower width and the portion of the second electrode 816 between the holes VA10 has a narrower width, but the disclosure is not limited thereto.

In the present embodiment, the signal lines 820, 830, and 840 are located between two adjacent transistors 810A and 810B. The signal line 840 is also located between two adjacent transistors 810C and 810D. The signal line 820 may be connected to the gate 818 of the transistor 810C to provide a control signal, and the signal line 830 may be connected to the first electrode 814 of the transistor 810C to provide a data signal. The signal line 840 may be connected to other transistors not shown. Moreover, in FIG. 10, the second electrode 816 of the transistor 810A may be connected to the second electrode 816 of the transistor 810C, and the second electrode 816 of the transistor 810B may be connected to the second electrode 816 of the transistor 810D. At the same time, the gate 818 of the transistor 810C may be connected to the gate 818 of the transistor 810D via a connecting line 850. In this way, the gate 818 of the transistor 810B and the gate 818 of the transistor 810D may be connected to the same signal line 820. The circuit 800 may be used as an implementation of implementing the circuit 700, but the disclosure is not limited thereto.

In some embodiments, the signal line 820 and the gate 818 of the transistor 810C may be different layers, and the signal line 820 may be electrically connected to the gate 818 of the transistor 810C via a hole VA11. The signal line 820 may have a variable width, for example, a first width W820A of the signal line 820 is different from a second width W820B, and the second width W820B is greater than the first width W820A, for example, wherein the hole VA11 is overlapped with a portion of the signal line 820 having the second width W820B. Since the gate 818 of the transistor 810C and the gate 818 of the transistor 810D share the signal line 820, the number of signal lines may be reduced. Therefore, the circuit 800 allows the transistors 810A to 810D to be arranged in a dense manner, thereby reducing the area of the peripheral region 112 (indicated in FIG. 1) where electronic elements need to be disposed. In some embodiments, at least two adjacent signal lines 820, 830, and 840 may be different layers, so that the signal lines 820, 830, and 840 may be closely arranged in the horizontal direction (X-axis), but the disclosure is not limited thereto.

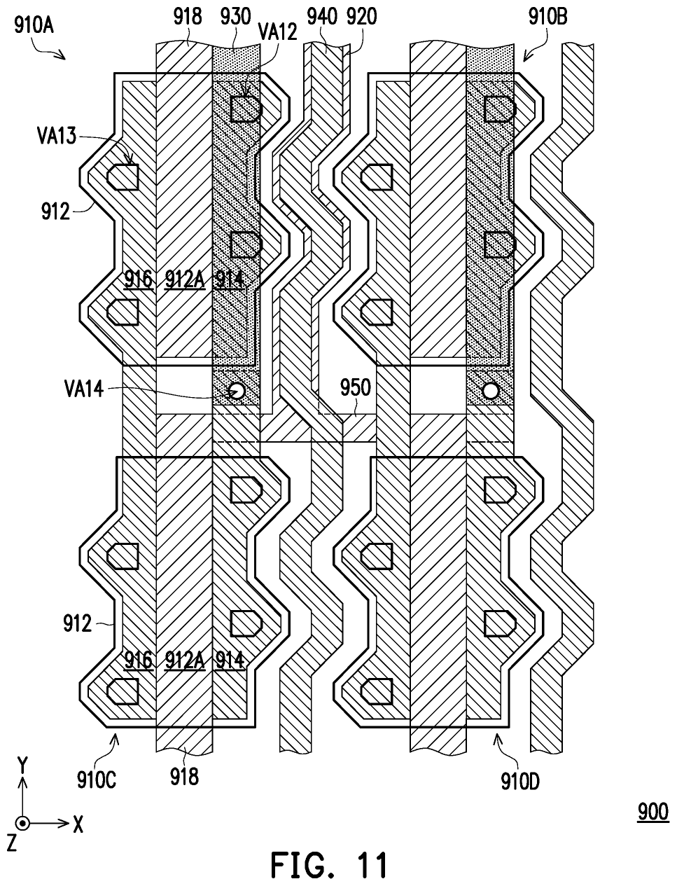

FIG. 11 is a partial schematic diagram of a circuit applied to the display device of FIG. 1. A circuit 900 of FIG. 11 may be disposed on the substrate 110 of FIG. 1, and specifically disposed on the peripheral region 112 of FIG. 1. The circuit 900 includes a plurality of transistors 910A to 910D and a plurality of signal lines 920, 930, and 940. The transistors 910A to 910D are arranged in an array. The transistor 910A and the transistor 910B are arranged in a column in the horizontal direction (X-axis), and the transistor 910C and the transistor 910D are arranged in another column in the horizontal direction (X-axis). The transistor 910A and the transistor 910C are arranged in a row in the longitudinal direction (Y-axis), and the transistor 910B and the transistor 910D are arranged in another row in the longitudinal direction (Y-axis). Each of the transistors 910A to 910D includes a channel layer 912, a first electrode 914, a second electrode 916, and a gate 918. The channel layer 912 has a channel region 912A. The channel region 912A is overlapped with the gate 918 and the first electrode 914 and the second electrode 916 are located at different sides of the channel region 912A. The first electrode 914 and the second electrode 916 may be electrically connected to the semiconductor layer 912 via holes VA12 and VA13 respectively. The specific structure of the transistors 910A to 910D may be implemented by any of the transistors 210, 310, 410, and 510.

In the present embodiment, the gate 918 of the transistor 910C may be connected to the gate 918 of the transistor 910D via a connecting electrode 950, and the signal line 920 may be connected to the connecting electrode 950. Therefore, the transistor 910C and the transistor 910D may receive the same control signal (or be connected to the same control signal line). The signal line 930 may be connected to the second electrode 916 of the transistor 910C, and specifically electrically connected to the second electrode 916 of the transistor 910C via a hole VA14. The signal line 940 may be connected to other transistors not shown in the circuit 900. In some embodiments, the connecting electrode 950 may be extended in the direction of the X-axis to overlap or even exceed the second electrode of another transistor (such as the transistor 910D), so as to be connected to other transistors, so as to implement serial connection of a plurality of transistors. Moreover, the second electrode 916 of the transistor 910A and the second electrode 916 of the transistor 910C may be connected to each other, the second electrode 916 of the transistor 910B and the second electrode 916 of the transistor 910D may be connected to each other, and the gate 918 of the transistor 910A and the gate 918 of the transistor 910B may be connected to the same control signal. In this way, the circuit 900 may be an implementation of the circuit 700.

In the present embodiment, the signal line 920 and the signal line 940 are different layers, and the signal line 920 and the signal line 940 may be overlapped with each other. In addition, the signal line 930 is overlapped with the first electrode 914 of the transistor 910A, for example, and is in a different layer from the first electrode 914 of the transistor 910A. In this way, the circuit 900 includes a structure in which different signal lines are overlapped, and the signal lines and the transistors are overlapped, so as to reduce the element layout area and thus be applicable to high element density designs. In some embodiments, the circuit 900 may be implemented using the layers recited in FIG. 6. For example, the gate 918 of the transistors 910A to 910D may be manufactured using the conductive layer M1 shown in FIG. 6, the first electrode 914 and the second electrode 916 of the transistors 910A to 910D may be manufactured using the conductive layer M2 shown in FIG. 6, the signal line 920 is manufactured by, for example, the conductive layer M1 of FIG. 6, and the signal line 940 is manufactured by, for example, the conductive layer M2 of FIG. 6. In addition, the signal line 930 overlapped with the first electrode 914 of the transistor 910A may be manufactured using any of the conductive layers M0, M3, M4, ITO1, ITO2, and ITO3.

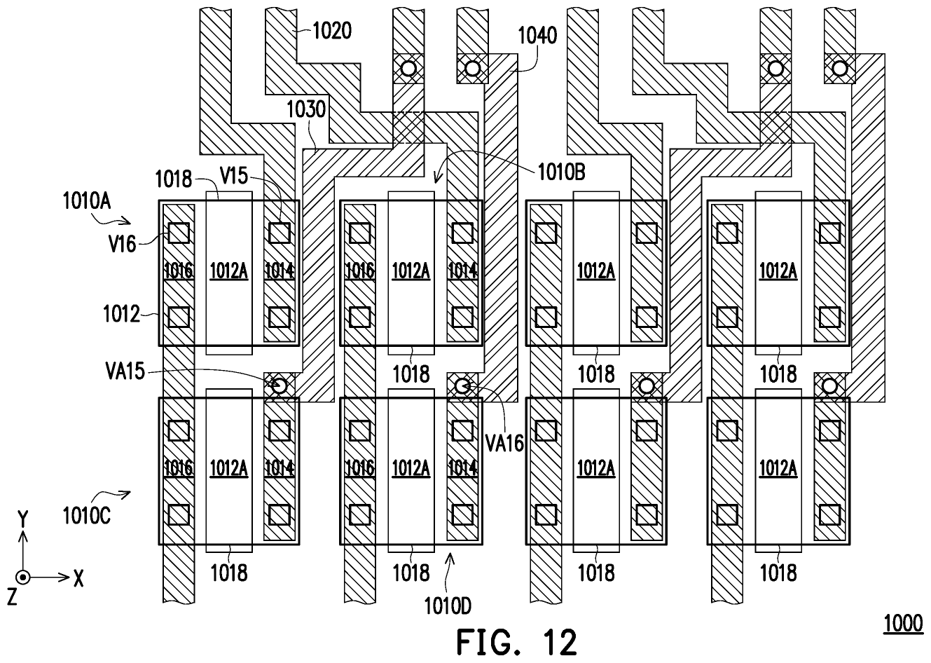

FIG. 12 is a partial schematic diagram of a circuit applied to the display device of FIG. 1. A circuit 1000 of FIG. 12 may be disposed on the substrate 110 of FIG. 1, and specifically disposed on the peripheral region 112 of FIG. 1. The circuit 1000 includes a plurality of transistors 1010A to 1010D (four of which are marked in FIG. 12 for illustration) and signal lines 1020, 1030, and 1040. The transistors 1010A to 1010D are arranged in an array, wherein the transistor 1010A and the transistor 1010B are arranged in a column in the horizontal direction (X-axis), and the transistor 1010C and the transistor 1010D are arranged in another column in the horizontal direction (X-axis). The transistor 1010A and the transistor 1010C are arranged in a row in the longitudinal direction (Y-axis), and the transistor 1010B and the transistor 1010D are arranged in a row in the longitudinal direction (Y-axis). In the present embodiment, each of the transistors 1010A to 1010D includes a channel layer 1012, a first electrode 1014, a second electrode 1016, and a gate 1018. The channel layer 1012 has a channel region 1012A. The channel region 1012A is overlapped with the gate 1018 and the first electrode 1014 and the second electrode 1016 are located at different sides of the channel region 1012A. The first electrode 1014 and the second electrode 1016 may be electrically connected to the semiconductor layer 1012 via holes VA15 and VA16 respectively. The specific structure of the transistors 1010A to 1010D may be implemented by any of the transistors 210, 310, 410, and 510, but the disclosure is not limited thereto. In addition, for the convenience of illustration, the connecting manner of the gate 1018 of the transistors 101A to 1010D is omitted in FIG. 12, and the gate 1018 is schematically shown.

In the present embodiment, the signal line 1020 may be connected to the first electrode 1014 of the transistor 1010B, and the signal line 1020 and the first electrode 1014 and the second electrode 1016 of the transistors 101A to 1010B are, for example, the same layer. The signal line 1030 may be connected to the first electrode 1014 of the transistor 1010C, and the signal line 1030 is disposed between the transistor 101A and the transistor 1010B. The signal line 1040 may be connected to the first electrode 1014 of the transistor 1010D and disposed adjacent to the transistor 1010B. In addition, the signal line 1030 and the first electrode 1014 and the second electrode 1016 of the transistors 101A to 1010B may be different layers. Accordingly, the signal line 1030 and the first electrode 1014 and the second electrode 1016 of the transistors 101A to 1010B may be different layers, and the signal line 1030 may be electrically connected to the first electrode 1014 of the transistor 1010C via the hole VA15. Similarly, the signal line 1040 and the first electrode 1014 and the second electrode 1016 of the transistors 101A to 1010B may be different layers, and the signal line 1040 may be electrically connected to the first electrode 1014 of the transistor 1010D via the hole VA16. In addition, the signal line 1020 and the signal line 1030 may be staggered with each other to achieve the desired electrical connection relationship. In the circuit 1000, the signal line 1030 and the signal line 1040 may have a plurality of turns, thereby allowing the transistor 1010A and the transistor 1010C to be aligned and form a row in the longitudinal direction (Y-axis), and the transistor 1010B and the transistor 1010D are aligned and form a row in the longitudinal direction (Y-axis). Such a layout design helps to increase the arrangement density of the transistors 101A to 1010D, and is beneficial for application in high-resolution design.

Based on the above, the display device of an embodiment of the disclosure includes a plurality of transistors in the peripheral region. The first electrode and the second electrode located at different sides of the channel region in the transistors are designed to be non-linearly symmetrical to each other, thereby reducing the arrangement area of the transistors and allowing a high arrangement density design. Signal lines may be disposed between the transistors. Adjacent signal lines may be different layers to allow dense arrangement of the signal lines. The signal lines may be overlapped with each other, or even overlapped with the transistors. The gate of the transistors may share the signal lines to reduce the number of signal lines. The display device of an embodiment of the disclosure facilitates application in products with high resolution and/or products with narrow borders.

Lastly, it should be noted that the above embodiments are used to describe the technical solution of the disclosure instead of limiting it. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

What is claimed is:

1. A display device, comprising:
a substrate having a peripheral region; and
a circuit disposed on the peripheral region and comprising a plurality of transistors, wherein one of the plurality of transistors comprises:
a semiconductor layer comprising a channel region;
a first electrode disposed at a side of the channel region and comprising a first portion; and
a second electrode disposed at another side of the channel region and comprising a second portion, wherein in a horizontal direction, a width of the first portion of the first electrode is greater than a width of the second portion of the second electrode.

2. The display device of claim 1, wherein the circuit comprises a multiplexer circuit or a gate driving circuit.

3. The display device of claim 1, wherein the first electrode is a source or a drain.

4. The display device of claim 1, wherein the second electrode is a source or a drain.

5. The display device of claim 1, wherein the first portion is electrically connected to the semiconductor layer via a hole.

6. The display device of claim 5, further comprising an insulating layer disposed on the substrate, and the hole penetrates through the insulating layer.

7. The display device of claim 1, wherein the second electrode further comprises a third portion, the third portion is adjacent to the second portion, and the third portion is electrically connected to the semiconductor layer via another hole.

8. The display device of claim 7, wherein a width of the third portion is greater than a width of the second portion of the second electrode.

9. The display device of claim 7, wherein the first electrode further comprises a fourth portion, the fourth portion is adjacent to the first portion, and the fourth portion is electrically connected to the semiconductor layer via another hole.

10. The display device of claim 9, wherein a width of the third portion is greater than a width of the second portion, and a width of the first portion is greater than a width of the fourth portion.

11. The display device of claim 1, wherein the first electrode has a curved outer edge, the outer edge has a first bending angle, and the first bending angle is 100 degrees to 160 degrees.

12. The display device of claim 11, further comprising a signal line disposed between adjacent two of the plurality of transistors, and the signal line has a second bending angle, and a difference between the second bending angle and the first bending angle is within 10 degrees.

13. The display device of claim 12, wherein a separation distance between an edge of the signal line and the outer edge is substantially maintained constant.

14. The display device of claim 1, further comprising a first signal line and a second signal line, wherein the first signal line and the second signal line are disposed between adjacent two of the plurality of transistors, and the first signal line and the second signal line are different layers.

15. The display device of claim 14, further comprising a plurality of pixel structures, wherein the substrate also has a display region adjacent to the peripheral region and the plurality of pixel structures are disposed in the display region, and the first signal line and the second signal line respectively control the plurality of pixel structures in different rows.

16. The display device of claim 15, wherein the first signal line and the second signal line are adjacent to each other in a horizontal direction.

17. The display device of claim 1, further comprising a signal line, wherein the second electrode of one of the transistors and the second electrode of another of the transistors are commonly connected to the signal line.

18. The display device of claim 1, further comprising a control line, wherein both one of the transistors and another transistor are controlled by the control line.

19. The display device of claim 1, further comprising a connecting line, wherein a gate of one of the transistors is connected to a gate of another transistor via the connecting line.

20. The display device of claim 1, further comprising a signal line, wherein a gate of one of the transistors and a gate of another transistor are commonly connected to the signal line.
